(19) United States
(12) Patent Application Publication
(10) Pub. No.: US 2009/0250804 A1
(43) Pub. Date: Oct. 8, 2009

(54) LEADFRAME-BASED IC-PACKAGE WITH SUPPLY-REFERENCE COMB

(75) Inventor: Victor Kaal, Ruurlo (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/092,613

(22) PCT Filed: Nov. 6, 2006
(86) PCT No.: PCT/IB06/54130

§ 371 Date: Feb. 19, 2009

Related U.S. Application Data
(60) Provisional application No. 60/735,104, filed on Nov. 8, 2005.

(51) Int. Cl. H01L 23/495

(52) U.S. Cl. 257/692; 257/E23.031; 257/690

(57) ABSTRACT

An IC package includes a leadframe-diepad (112) and a supply-reference comb (114) for interconnecting a die (110) and the package I/O pins (124) in a manner that facilitates substantially ideal EMC performance. The leadframe-diepad includes a diepad-finger (118) and an elongated portion. The leadframe-diepad and the diepad-finger are connected to ground-reference bondpads (128). The supply-reference comb has an elongated spine portion (120) and a finger that is arranged very close to and along the elongated portion of the leadframe-diepad and the diepad-finger respectively for facilitating electromagnetic coupling therebetween and for facilitating local tying of return currents. The supply-reference comb also has a plurality of fingers (116) extending outwardly from the elongated spine portion in a substantially common direction that provides sufficient space in between the fingers for the I/O pins.

The present invention is directed generally to packaged integrated circuits, and in particular, packaged integrated circuits with electromagnetic interference issues.

Modern integrated circuits (ICs) often have high-speed input/output (I/O) bondpads that require special attention with respect to electromagnetic compatibility (EMC). EMC is affected by the conductive circuit loop formed between the power supply and ground. An example conductive loop includes the power supply path within an IC, IC package pins, bond wires connecting the IC I/O bondpads to the IC package pins, a metal leadframe upon which the IC is mounted, and an external power supply decoupling capacitor. Addressing an IC's EMC often requires many peripheral ground and supply IC bondpads, and with an ever-increasing number of bondpads per available package pins, the effect of the interface between the bondpads and package pins can be critical to circuit performance.

Various approaches have been proposed to address this interface. For example, U.S. Pat. No. 5,563,443 uses a bus bar on an IC for a lead-over-chip (LOC) type of leadframe. Similarly, U.S. Pat. No. 5,763,945, teaches using extended leads and U-shapes to construct bars for multiple (supply) bondpad connections. In U.S. Pat. No. 6,144,089, another approach also uses bars for a LOC configuration with the bars being located over the chip and used for supply connection to the die. The bars are also able to connect multiple bondpads to a fewer number of package pins. However, these variously shaped bars do not sufficiently account for EMC considerations.

For these and other leadframe package designs, the EMC of the IC is often compromised due to a limited number of package pins available in the package of choice. One example occurs when bondpads are bondwired to dedicated leadfingers, or to the leadframe-diepad for ground connections. As discussed in the book entitled, “Deep-Submicron CMOS ICs” (2nd edition, Harry Veendrick, 2000), high-speed peripheral I/O IC signal tracks and output drivers with high current transient capabilities are a major source for electromagnetic disturbances at the IC/PCB level and for supply noises at chip-level. These adverse effects can be reduced by combining various approaches including: on-chip supply rings and pad-to-ring-connections local to the drivers; close and/or adjacent peripheral ground (Vssp) and supply tracks (Vddp) having a small enclosed area to allow for first-order cancellation of electromagnetic fields (via closely coupled supply-pair tracks); and I/O signal tracks located between peripheral ground and supply tracks to provide close coupling to their return paths.

The above and other difficulties continue to present challenges to managing EMC performance in leadframe-based IC packages while accommodating, for example, package types with pre-defined pin-counts and other economic motives.

The present invention is directed to overcoming the above-mentioned challenges and others related to the types of devices and applications discussed above. These and other aspects of the present invention are exemplified in a number of illustrated implementations and applications, some of which are shown in the figures and characterized in the claims section that follows.

Various aspects of the present invention are applicable to an integrated circuit package including an integrated circuit die, a plurality of I/O pins, a leadframe-diepad, and a supply-reference comb. The integrated circuit die has reference bondpads, including ground-reference bondpads and supply-reference bondpads, and a plurality of I/O bondpads where the plurality of I/O pins are arranged to connect to respective ones of the I/O bondpads. The leadframe-diepad is attached to the integrated circuit die and includes a diepad-finger and an elongated portion. The leadframe-diepad is electrically connected to the ground-reference bondpads. The supply-reference comb also has an elongated spine portion that is arranged adjacently along the elongated portion of the leadframe-diepad for facilitating electro-magnetic coupling therebetween and for facilitating local tying of return currents and which is electrically connected to the supply-reference bondpads. The supply-reference comb also has a plurality of fingers extending outwardly from the elongated spine portion in a substantially common direction and provides sufficient space between the fingers for the I/O pins. The comb fingers facilitate electromagnetic coupling with the diepad-finger and the I/O pins.

Another aspect of the present invention is directed to leadframe-based IC packages having a supply-reference comb that permits the number of supply and ground package pins to be different from the number of supply and ground bondpads. The supply-reference comb is also arranged to limit the drop in EMC performance due to the reduction in the number of package pins by maintaining an increased level of electromagnetic coupling.

The above summary of the present invention is not intended to describe each illustrated embodiment or every implementation of the present invention. The figures and detailed description that follow more particularly exemplify these embodiments.

The invention may be more completely understood in consideration of the following detailed description of various embodiments of the invention in connection with the accompanying drawings, in which:

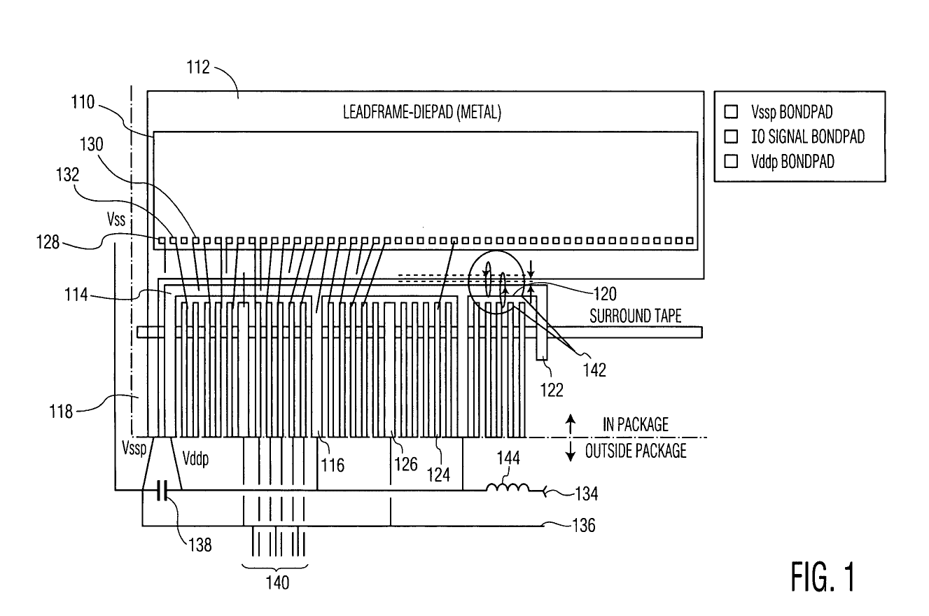

FIG. 1 is a semiconductor package arrangement according to one example embodiment of the present invention; and

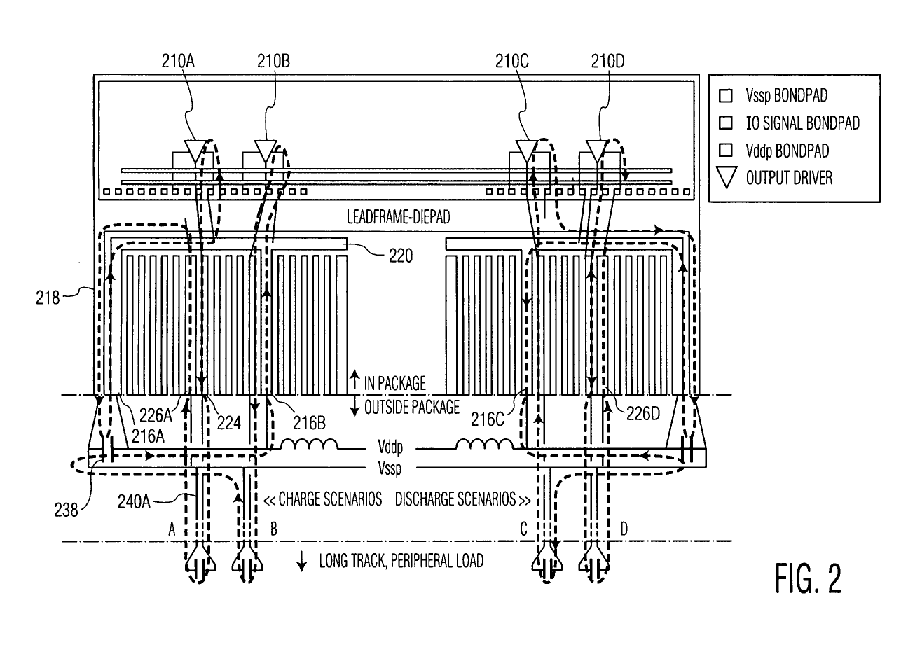

FIG. 2 is another semiconductor package arrangement with illustration of charge and discharge loop scenarios, according to an example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention as defined by the appended claims.

The present invention is believed to be useful for designing IC packages that accommodate package types with pre-defined pin-counts while enhancing EMC performance of the IC. While the present invention is not necessarily limited to such applications, various aspects of the invention may be appreciated through a discussion of various examples using this context.

In connection with an example embodiment of the present invention, an integrated circuit package includes an integrated circuit die, a plurality of I/O pins, a leadframe-diepad, and a supply-reference comb. The integrated circuit die has reference bondpads, including ground-reference bondpads and supply-reference bondpads, and a plurality of I/O bondpads where the plurality of I/O pins are arranged to connect to respective ones of the I/O bondpads. The leadframe-diepad is attached to the integrated circuit die and includes a diepad-finger and an elongated portion. The leadframe-diepad is electrically connected to the ground-reference bondpads. The supply-reference comb also has an elongated spine portion that is arranged adjacently along the elongated portion of the leadframe-diepad for facilitating electromagnetic coupling therebetween and for facilitating local tying of return currents and which is electrically connected to the supply-reference bondpads. The supply-reference comb also has a plurality of fingers extending outwardly from the elongated spine portion in a substantially common direction and provides sufficient space between the fingers for the I/O pins. The comb fingers facilitate electromagnetic coupling with the diepad-finger and the I/O pins.

The inclusion of a supply-reference comb between the diepad and the leadfingers improves the IC's EMC with respect to several aspects. For example, supply bondpads can be connected even when there are fewer supply package pins. Also, more ground bondpads can be connected than the available ground package pins would typically allow because the leadframe-diepad can be used for the ground bondpad connection and the supply-reference comb locally ties return currents. Without the supply-reference comb, return currents would be untied and could introduce noise at sensitive die locations. Accordingly, an IC package is implemented with fewer pins, less cost, larger pin-pitch (which may allow cheaper wave-solder PCB manufacture), and adequate EMC performance. Moreover, the connection of the leadframe to an external decoupling capacitor influenced by a supply-reference comb reduces the enclosed loop area of the decoupling currents. This reduces the effective inductances, resulting supply noise, and electromagnetic radiation.

In a more particular example embodiment, a leadframe-based package includes a supply-reference comb having one or more pin connections (or fingers), where more fingers can be configured to further improve EMC performance and mechanical stability. The supply-reference comb may also include fingers that support the comb by resting on surround tape in the package. These fingers are arranged in a substantially common direction so that they extend away from the back (or spine) portion of the comb without crossing or overlapping which would short the I/O pin connections. Thus, the support fingers do not impact on the total pin count. The back of the supply-reference comb is located as close as possible to the leadframe-diepad, for optimal coupling to, and local tying of, the return currents at the adjacent edge of the leadframe-diepad. Further, the leadframe-diepad has at least one leadfinger that is connected to the leadframe-diepad and is located adjacent or at least as close as possible to a pin connection of the supply-reference comb. It will be appreciated that optimizing this coupling contemplates the practicable aspects of IC manufacturing constraints and circuit power/signal attributes for a particular application; thus, implementing such conductive paths as close as possible to one another optimizes performance only as is practicable.

According to one example embodiment, FIG. 1 shows such a leadframe-based package including a die 110 attached to a leadframe having a supply-reference comb. The leadframe includes both the leadframe-diepad 112 upon which the die 110 is attached and a supply-reference comb 114. The supply-reference comb 114 includes comb fingers (one example finger being labeled as reference numeral 116), one of which is located near a diepad-finger 118 that is connected to the leadframe-diepad 112. The supply-reference comb is also configured to have a back portion 120 that is closely aligned with an elongated portion of the leadframe-diepad 112. In certain embodiments the supply-reference comb 114 also includes one or more support fingers 122 which rest on surround tape or other support fixtures in the package and do not affect the pin count of the package. Other pin connections included in the leadframe are I/O signal pins (one example being labelled as reference numeral 124) and peripheral-ground pins (one example being labelled as reference numeral 126).

The die 110 has several bondpads including peripheral-ground bondpads (one example being labelled as reference numeral 128), supply bondpads (one example being labelled as reference numeral 130), and I/O signal bondpads (one example being labelled as reference numeral 132). The peripheral-ground bondpads connect to the on-die peripheral ground ring and the supply bondpads connect to the on-die peripheral supply ring. The respective bondpads are connected to the leadframe-diepad 112, the supply-reference comb 114, and I/O pins 124 respectively via bondwires. The connections between the peripheral-ground bondpads 128 and the leadframe-diepad 112 include connections to the leadfinger 118. Also, the connections between the supply bondpads 130 and the supply-reference comb 114 include connections to both the back portion 120 and the comb fingers 116 of the supply-reference comb 114.

The IC package is connected to external circuitry. For example, the IC is fed by a peripheral power supply at node 134. The coil 144 keeps the high-frequency currents local. The peripheral-ground connection is at node 136. Peripheral supply decoupling is provided by a decoupling capacitor 138 and three peripheral-ground return paths 140 are included. As output drivers (not shown in FIG. 1) drive high currents and current transients for high-speed I/O switching, large (therefore external) decoupling capacitors such as capacitor 138, are used for decoupling. The decoupling capacitor 138 is located close to the diepad-finger 118 and the comb finger 116 that is located near the leadfinger 118.

The configuration of the supply-reference comb creates a low-inductance path for large current transients. For example, close coupling between the supply and ground signals occurs along the back portion of the comb 120 and the comb finger 116 that is located near the diepad-finger 118, as these portions are located near the elongated edge of the leadframe-diepad 112 and near the diepad-finger 118. An example of this close signal coupling is illustrated in FIG. 1 at the encircled region 142 that overlaps the leadframe-diepad 112 and the back portion of the comb 120. This configuration keeps the enclosed area of the high-frequent decoupling current loop as small as possible to realize smaller effective inductance, less voltage bounce, and less electromagnetic radiation. These closely-adjacent reference paths tie the decoupling currents to these specific areas such that they will not flow throughout the leadframe-diepad 112 where they would otherwise introduce noise to sensitive areas of the die 110. Moreover, this configuration allows the peripheral-ground bondpads 128 to be down-bonded to the leadframe-diepad 112 and also allows other parts of the leadframe-diepad 112 to be connected and used as common circuit ground for other functionality.

FIG. 2 illustrates another example embodiment of an IC package including illustration of the charge and discharge current loops for the output drivers 210 within the package. For following these different current loops, these output drivers are denoted (from left to right) as 210A, 210B, 210C and 210D, and their corresponding current loop scenarios are similarly labeled: A, B, C and D. An example charge loop with a peripheral-ground pin as the nearest coupled pin is shown with respect to output driver 210A. More specifically, the output driver 210A provides a charge on an I/O pin 224 with a peripheral-ground pin 226A being the nearest coupled conductor. With the I/O pin 224 driving an external circuit, the actual charge current is supplied from capacitor 238 via comb finger 216A and part of the spine 220, through the supply of driver 210A to the driver output connected to I/O pin 224. The return path is formed by track 240A which is located the closest to I/O pin 224 and connects to peripheral-ground pin 226A. The return path continues through the leadframe-diepad and a diepad-finger 218 close to the area of the spine 220 and comb finger 216A used for charging and closes the loop at the ground connection of capacitor 238. The above-described charge loop has a small enclosed are.

These flows are similarly illustrated for each of output drivers 210B, 210C and 210D. Scenario B shows the flow direction for the output driver 210B providing a charge with the nearest coupled conductor being a Vddp comb-finger 216B. Scenario C shows the flow direction for the output driver 210C providing a discharge with the nearest coupled conductor being a Vddp comb-finger 216C. Scenario D shows the flow direction for the output driver 210D providing a discharge with the nearest coupled conductor being a Vssp leadfinger 226D.

Input or output signals carry high current transients. Therefore, preferably a low-inductance (well-coupled) high-frequency current return path exists for each of the I/O signals, as shown in FIG. 2 with the supply-reference comb-fingers 216 and peripheral-ground pins 226 providing these paths. When lowering the supply pin to signal pin ratio, the enclosed loop area near some of the I/O leadfingers increases which decreases EMC performance.

With the IC package on a printed circuit board (PCB), the current return path can be implemented by one or more adjacent Vssp tracks or via PCB Vss plane if the PCB is implemented in more than two layers.

In another embodiment where external decoupling occurs, the supply-reference comb fingers are replaced by peripheral-ground reference pins as the source of high-frequency current return paths. Even if not used as a high-frequency current return path, the supply-reference comb fingers may still be needed to provide necessary support for a stable comb configuration. For example, the mechanical stability of the supply-reference comb limits the length of the back portion of the supply-reference comb in the absence of supply-reference comb fingers. Surround tape can provide a fixture point for the necessary mechanical support extensions of the back portion of the supply-reference comb, which also prevents an increase in pin count necessitated by mechanical considerations. Similarly, the supply-reference comb fingers can be used as the single source of high-frequency current return paths (e.g. all peripheral-ground reference pins would be replaced by supply-reference comb fingers).

In applications involving a die that has a staggered bondpad configuration, there may be bonding limitations. In one such configuration, for example, the inner bondpad row cannot be bond-wired to the leadframe-diepad and to the back portion of the supply-reference comb. In accordance with another aspect of the present invention, supply bondpads in this configuration are bonded directly to peripheral-ground pins or supply-reference comb fingers.

While certain aspects of the present invention have been described with reference to several particular example embodiments, those skilled in the art will recognize that many changes may be made thereto. For example, while the above-illustrated embodiments suggest a regular pattern for supply-reference comb fingers, peripheral-ground pins, and I/O signal pins, it is recognized that such patterns should be adapted to the parameters of the I/O signals and output drivers (e.g., slew-rate, regularity of signal) to obtain optimal EMC performance; for instance, EMC performance benefits from a coupling path adjacent to regular signals such as clock signals. Such variations and changes are not necessarily intended to depart from the spirit and scope of the present invention. Aspects of the invention are set forth in the following claims.

1. An integrated circuit package, comprising:
an integrated circuit die having reference bondpads, including peripheral-ground reference bondpads and supply-reference bondpads, and having a plurality of input/output (I/O) bondpads;
a plurality of I/O pins arranged to connect to respective ones of the I/O bondpads;
a leadframe-diepad attached to the integrated circuit die and having a diepad-finger and an elongated portion, the leadframe-diepad being electrically connected to the peripheral-ground reference bondpads;
a supply-reference comb having an elongated spine portion arranged adjacently along the elongated portion of the leadframe-diepad for facilitating coupling therebetween and local tying of return currents, and having a plurality of fingers extending outwardly from the elongated spine portion in a substantially common direction and providing sufficient space therebetween for the I/O pins, the supply-reference comb being electrically connected to the supply-reference bondpads.

2. The integrated circuit package of claim 1, wherein the supply-reference comb is arranged relative to the leadframe-diepad as a function of electromagnetic compatibility.

3. The integrated circuit package of claim 1, wherein the supply-reference comb is arranged relative to the leadframe-diepad to enhance electromagnetic compatibility between high-frequent current respectively carried by the peripheral-ground reference bondpads, the supply-reference bondpads, and the I/O bondpads.

4. The integrated circuit package of claim 1, wherein the diepad-finger is fused to the leadframe-diepad.

5. The integrated circuit package of claim 4, wherein one of the plurality of fingers extending outwardly from the elongated spine portion of the supply-reference comb is located adjacent to the diepad-finger.

6. The integrated circuit package of claim 4, wherein one of the plurality of fingers extending outwardly from the elongated spine portion of the supply-reference comb is located near the diepad-finger.

7. The integrated circuit package of claim 1, wherein the I/O pins are arranged to connect respective ones of the I/O bondpads to circuitry that is external to the package.

8. The integrated circuit package of claim 7, wherein the I/O pins are arranged relative to the plurality of supply-reference comb fingers to limit high-frequency current path loop area.

9. The integrated circuit package of claim 7, wherein the I/O pins are arranged relative to the plurality of supply-reference comb fingers and to a plurality of peripheral-ground reference fingers to limit high-frequency current path loop area.

10. The integrated circuit package of claim 1, wherein one of the plurality of fingers extending outwardly from the elongated spine portion of the supply-reference comb is located adjacent to the diepad-finger and the I/O pins are arranged relative to the plurality of supply-reference comb fingers to limit high-frequency current path loop area.

11. The integrated circuit package of claim 1, wherein each of the reference bondpads is connected.

12. The integrated circuit package of claim 1, wherein peripheral-ground reference bondpads are connected to the leadframe-diepad.

13. The integrated circuit package of claim 1, wherein peripheral-ground reference bondpads are connected to peripheral-ground fingers.

14. The integrated circuit package of claim 1, wherein peripheral-ground fingers are connected to the leadframe-diepad.

15. The integrated circuit package of claim 1, wherein each of the supply-reference bondpads is connected to the supply-reference comb.
